(19) United States
(12) Patent Application Publication
(10) Pub. No.: US 2023/0209703 A1
(43) Pub. Date: Jun. 29, 2023

(54) Method for manufacturing a component

(71) Applicant: Scio Holding GmbH, Linz (AT)

(72) Inventors: Marius Sillmann, Stuttgart (DE); Jürgen Goldmann, Lüdenscheid (DE); Franz Padinger, St. Marien (AT)

(21) Appl. No.: 17/927,204

(22) PCT Filed: May 21, 2021
(86) PCT No.: PCT/EP2021/063652

§ 371 Date: Nov. 22, 2022

(30) Foreign Application Priority Data
May 22, 2020 (DE) 10 2020 003 086.6
May 22, 2020 (DE) 10 2020 003 087.4
May 22, 2020 (DE) 10 2020 003 088.2

(51) Int. Cl. H05K 1/02; B60R 13/00; H05K 3/12; H05K 1/18; H05K 3/30

(52) U.S. Cl. CPC H05K 1/0274; B60R 13/005; H05K 3/1216; H05K 1/185; H05K 3/305; H05K 2201/10106; H05K 2201/10022; H05K 2201/0108; H05K 2201/0129; H05K 2201/10303; H05K 2201/09736

(57) ABSTRACT

The invention relates to a method for manufacturing a component (1) comprising a printed circuit board (2) and a number of electrical components (3) arranged thereon. According to the invention, the electrical components (3) are pre-fixed on the printed circuit board (2), which is formed of plastic, by means of a fixing adhesive (9) and then completely encapsulated with an UV-adhesive (8).

The invention relates to a method for manufacturing a component according to the features of the preamble of claim 1.

As described in DE 10 2014 008 262 A1, the state-of-the-art version of the vehicle is known for its backlit car emblem, in which only the car logo is illuminated. The LED backlit car brand emblem in the rear area of a motor vehicle is coupled with the parking light and the lower-beam headlight as well as directly with the license plate illumination in the rear area and is also switched on and off with this.

The invention is based on the task of specifying a method for manufacturing a component which has been improved compared to the state of the art.

The task is solved according to the invention by a method for manufacturing a component comprising the features of claim 1.

Advantageous embodiments of the invention are the subject of the subsidiary claims.

According to a first aspect, a method for the manufacturing of a component is provided comprising a printed circuit board and a number of electrical components arranged thereon, according to the invention, the electrical components are pre-fixed to the printed circuit board formed from plastic by means of a fixing adhesive and then completely encapsulated a UV-adhesive, i.e. with an adhesive that can be cured by means of ultraviolet radiation.

This results in a two-stage bonding of the electrical components. During curing or polymerization of the adhesive, water can basically be split off. This can damage the PCB tracks and contacts of the electrical conduit. The two-stage bonding has the advantage that a thin layer of fixing adhesive is applied first, which cures, whereby the resulting water escapes. In the case of complete encapsulation, water is again produced during curing and polymerization of the adhesive. Because the corrosion-sensitive parts, such as PCB tracks and contacts of the electrical components, are already covered by the first, essentially cured adhesive layer, they are protected from the moisture that occurs during of the second adhesive layer. This is particularly advantageous if the component to be manufactured in this way comprises a cavity that is to be poured out and which is almost completely sealed after encapsulating, so that the moisture produced during polymerization can only escape slowly. In the case of a component consisting of two or more parts to be glued together, the fixing adhesive is initially exposed after the first adhesive step so that it can dry quickly and thoroughly.

The component formed in this case is in particular an emblem, in particular an illuminated emblem, and in particular a brand emblem of a vehicle manufacturer, which can be attached to a vehicle. The electrical components, which are pre-fixed by means of the fixing adhesive, comprise in particular LEDs (light-emitting diodes) for illuminating the emblem. By means of the method according to the invention, an environmentally stable and light-optimized adhesion of the electrical components to the printed circuit board, made of plastic, is ensured.

In particular for the formation of the emblem, the printed circuit board, in particular made of polymethylmethacrylate (PMMA), with the electrical components prefixed thereon is advantageously connected, in particular glued, to a cover after the fixing adhesive used for prefixing has cured. The cover, for example, is formed from of polycarbonate (PC) and/or acrylonitrile-butadiene-styrene (ABS) and/or from one or more other materials. For example, the cover is chromium-plated, in which case it is formed, for example, from polycarbonate and acrylonitrile-butadiene-styrene (PC/ABS) or from acrylonitrile-butadiene-styrene (ABS) or from one or more other materials. The bonding is carried out in particular by completely filling an adhesive channel between the printed circuit board and the cover, which is also referred to as the chrome cover if it is chrome-plated, with the UV-adhesive and then irradiating UV-adhesive through the translucent printed circuit board by means of an UV-lamp, thereby curing it. This form of adhesion means that shear forces no longer act directly on the individual electrical components, but on the entire pre-fixation of all components of the component. As a result, the electrical components remain bonded to the PCB tracks of the printed circuit board and the component meets the general requirements for environmental influences by the method described.

By means of the method described here, the component, in particular the illuminated emblem, is thus manufactured in such a way that the electrical components are protected from environmental influences, which in particular lead to entry of moisture and thus to corrosion of the PCB tracks, in particular also at temperatures between −30° C. and 80° C. and also at different operating conditions of the component. Furthermore, the method ensures that the LEDs produce a homogeneous lighting effect on the emblem.

Without the prefixing of the electrical components on the printed circuit board according to the invention, i.e. In the case of exclusive full encapsulation of the electrical components on the printed circuit board, the electrical components would also be protected, for example, at least at room temperature, but the coefficients of thermal expansion of all components of the component differ so much at large temperature differences that the shear forces that would be transferred from the UV-adhesive to the electrical components would be so great that the electrical components would be torn by the PCB tracks. Furthermore, no homogeneous light effect can be produced with this exclusive full encapsulation without the prior pre-fixation.

These disadvantages are thus avoided by the method described here. Pre-fixing the electrical components on the printed circuit board prevents the shear forces between the UV-adhesive and the electrical components from becoming too high. In addition, this protects the PCB tracks, which are made in particular of silver, from a chemical reaction with the UV-adhesive.

The electrical components are pre-fixed on the printed circuit board, for example, by applying the fixing adhesive for pre-fixing the electrical components at least in sections to the printed circuit board and the electrical components by means of a valve, in particular by means of a jet-valve, on assembly device designed in particular as a SMD-circuit board assembler, by means of which the electrical components are applied to the printed circuit board, in particular in such a way that it wets the PCB tracks and encloses the electrical components and attaches them to the printed circuit board. In the case of LEDs, the fixing adhesive is advantageous applied in such a way that the LEDs are left free in the main direction of beam, i.e. are not covered with the fixing adhesive in order to avoid unwanted color effects of a light emitted by the LEDs, which would result from a change of medium, i.e. by an unwanted change of the medium which the light passes. As an alternative to applying the fixing adhesive using the placement device, the fixing adhesive can also be applied to different location and/or using a different device.

According to a second aspect of the invention, an electrical assembly is provided, comprising a printed circuit board and a number of LEDs arranged thereon, wherein
the printed circuit board is formed of plastic,
the LEDs being divided into a number of component groups, the LEDs of each component group being electrically connected in series and the component groups being electrically connected in parallel with each other, each component group comprising a number of electrical protective resistors electrically connected in series with the LEDs of the respective component group, wherein an electrical protective resistor and at least one LED are arranged alternately.

An electrical assembly comprises a printed circuit board and a number of LEDs (light emitting diodes) arranged thereon.

In particular, an electrical protective resistor and an LED are arranged alternately.

In addition, advantageously, a resistance value of the electrical protective resistors of the respective component group is higher than required for an allowable current flow through the LEDs of the respective component group. The allowable current flow is specified by the manufacturers of the LEDs. As a result, the LEDs are operated in normal operation with a current flow significantly below the maximum allowable current flow.

Furthermore, PCB tracks on the printed circuit board, which are formed in particular as silver PCB tracks by means of screen printing, comprise different thicknesses at different positions on the printed circuit board. In the top view, different thicknesses refer to PCB tracks with different widths, because the layer thickness as such cannot be changed in screen printing.

The electrical assembly according to the invention can be used, for example, to form an illuminated emblem, in particular to form an illuminated brand emblem of a vehicle manufacturer, which can be attached to a vehicle. In particular, when the electrical assembly is used in such a manner, cooling of the electrical assembly in a conventional manner is not possible. The solution according to the invention means that such cooling is not required, since this solution according to the invention achieves thermal optimization and thus a functioning thermal management of the electrical assembly.

Without the solution according to the invention, for example, when the LEDs are divided into groups of two and groups of three, each with a single protective resistor designed for an effective voltage of, for example, 10 V, failures of individual LED-groups would occur during prescribed electrical load tests, for example at a transient overvoltage of 17 V for 60 minutes, due to occur massive heat development of individual electrical protective resistors, which melt into the printed circuit board, which is formed in particular from a thermoplastic plastic and cut through the printed silver PCB tracks. The heat dissipation also occurs asymmetrically on the printed circuit board and particularly in the area of a voltage supply.

This is prevented by the solution according to the invention, because in the solution according to the invention, as described above, a variable thickness of the screen-printed PCB tracks is used in order to thereby achieve resistance control of the PCB tracks.

Furthermore, for thermal management, the optimization according to the invention is carried out by means of the electrical protective resistors, which are oversized in the solution according to the invention and are arranged delocalized on the printed circuit board, i.e. not one electrical protective resistor per component group, but the resistance value, which is also greater than required, is divided among several protective resistors per component group and these are arranged on the printed circuit board, in particular alternately one electrical protective resistor and one LED in each case. In this way, the solution according to the invention achieves a thermally stable electrical circuit on the printed circuit board made of plastic.

Without the solution according to the invention, the electrical assembly and thus the component designed in particular as an emblem would not be able to meet the electronic requirements. For example, an additional expensive ballast circuit board would then be required to reduce the voltage, which is avoided by the solution according to the invention.

According to a further aspect of the present invention, a method for electrically conductive contacting of a printed circuit board is provided. The printed circuit board is in particular formed of plastic. In the method, a contact pin, in particular made of brass, is pressed into the printed circuit board penetrating the printed circuit board, i.e. from one flat side towards an opposite flat side of the printed circuit board, in particular in a form-fitting manner fit, until a collar formation at a front end of the contact pin bears against a bottom of a groove-like recess in the printed circuit board. This frontal end is covered with a PCB track, in particular of silver, printed in the groove-like recess. The contact pin is crimped with a crimp sleeve. An electrical cable, in particular with a cable end sleeve, is inserted into the crimp sleeve, makes electrically conductive contact with the contact pin and is crimped to the crimp sleeve. A heat-shrinkable sleeve is arranged in a sealing manner, i.e. Shrunk on, over the contact pin, the crimp sleeve and at least in sections over the electrical cable, in particular over the cable end sleeve. Advantageous, the printed circuit board is assembled and/or bonded to at least one other component before the contact pin is crimped to the crimp sleeve.

The crimping of the crimp sleeve with the contact pin is carried out in particular in such a way that the contact pin is locked in its position in the printed circuit board by the crimp sleeve, whereby in particular a movement of the contact pin in the longitudinal direction of the contact pin is prevented or at least restricted by the crimp sleeve. In particular, the crimp sleeve prevents the contact pin from being pressed back against the press-in direction, which in particular keeps the contact pin in contact with conductive pastes and/or the PCB track at the frontal end of the contact pin in operation.

By means of the solution according to the invention, a useful and environmentally stable electrically conductive contacting for cables can be provided for industrial manufactured printed circuit boards, in particularly made of plastic, with in particular screen-printed PCB tracks. In particular, this solution according to the invention prevents the electrical conductive connection of the cable caused by temperature interactions and environmental influences from being disconnected.

In the case of direct electrically conductive contacting of the PCB tracks with the cable or other connecting elements, due to the different thermal expansion coefficients of the materials involved and due to a low connection force to the PCB tracks, even a thermally caused movement would be sufficient to separate the connection and thus lead to faults in the electrical contacting. This is avoided by the solution according to the invention.

The solution according to the invention is used, for example, for electrically conductive contacting of a printed circuit board of an emblem, in particular an illuminated emblem, in particular a brand emblem of a vehicle manufacturer, which can be attached to a vehicle.

The different aspects of the invention explained above can be applied independently or in any combination.

Examples of embodiments of the invention are explained in more detail below with reference to drawings.

Therein showing:

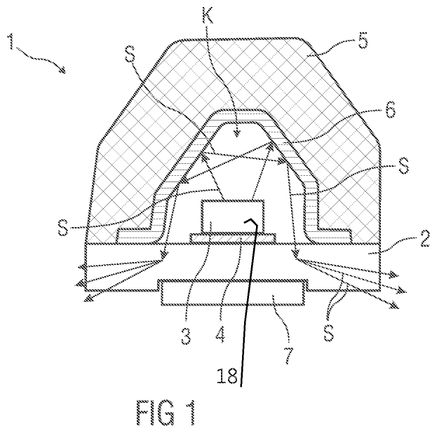

FIG. 1 schematically, a sectional view of an embodiment of a component without bonding of its components,

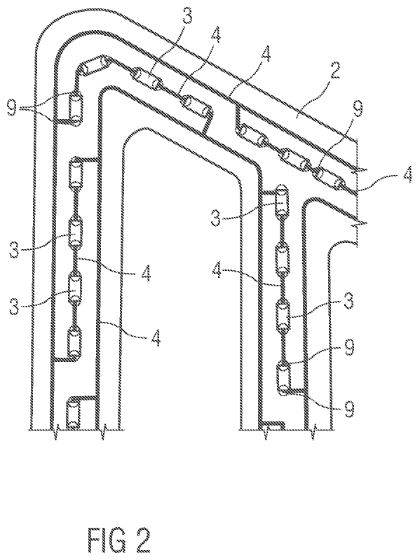

FIG. 2 schematically, a top view of a printed circuit board of the component with electrical components pre-fixed at certain points,

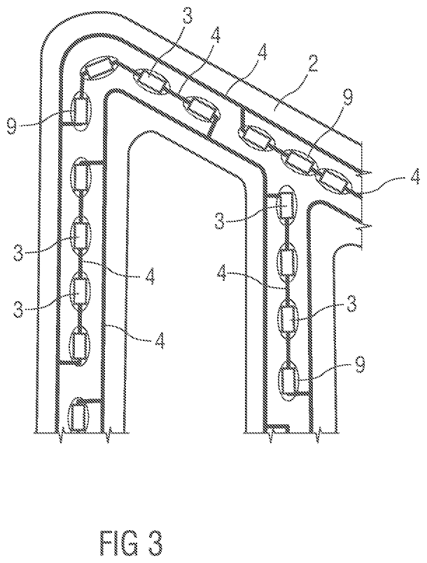

FIG. 3 schematically, a top view of a printed circuit board of the component with electrical components pre-fixed over a large area,

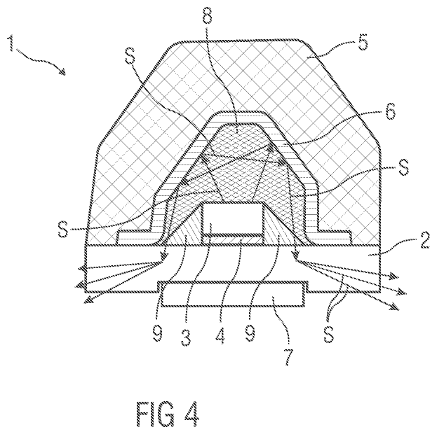

FIG. 4 schematically, a sectional view of a further embodiment of the component with bonded components,

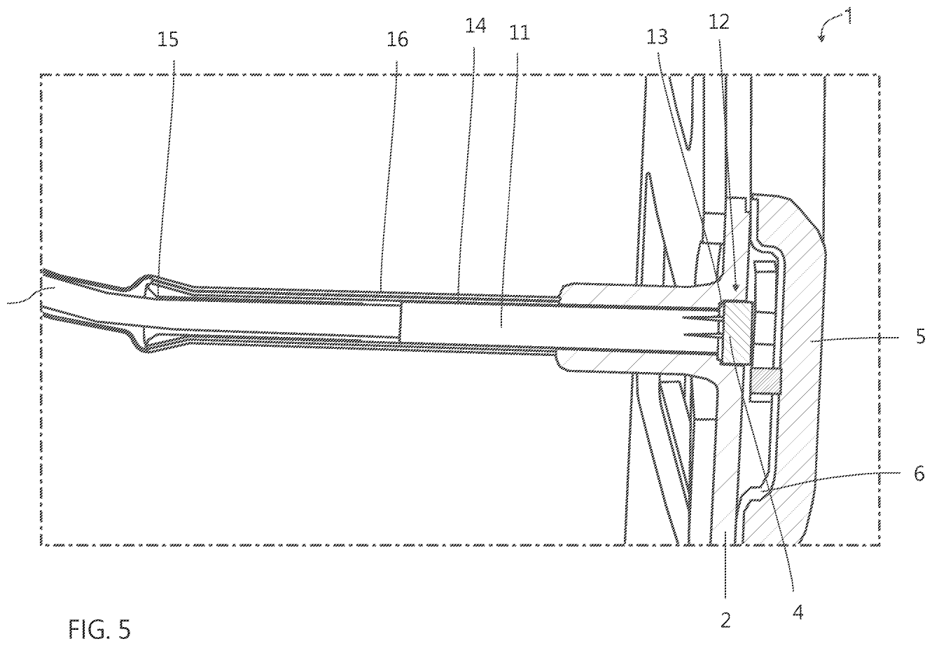

FIG. 5 schematically, a partial sectional view of the component, and

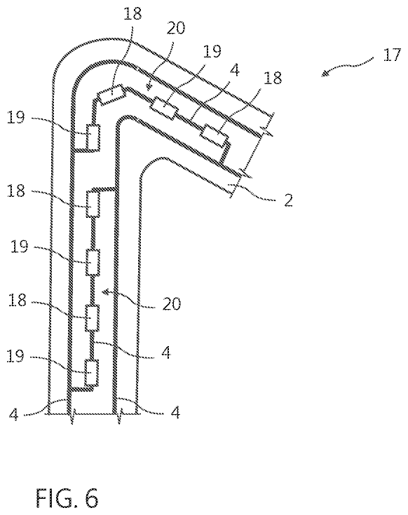

FIG. 6 schematically, in a top view of a section of an electrical assembly.

Corresponding parts are provided with the same reference signs in all figures.

With reference to FIGS. 1 to 4, a method of manufacturing a component 1 is described below. The component 1 comprises a printed circuit board 2 and a number of electrical components 3 arranged thereon.

In the example shown, the component 1 is an illuminated emblem, in particular a brand emblem of a vehicle manufacturer, which can be attached to a vehicle. The electrical components 3 comprise in particular LEDs for illuminating the emblem, and in the example shown additionally electrical resistances. They may also comprise further electrical components.

As already mentioned, component 1 comprises an assembly 17 with the printed circuit board 2, which is formed here from a particularly thermoplastic material, in the example shown from polymethylmethacrylate (PMMA). PCB tracks 4, in particular made of silver, are arranged on the printed circuit board 2. The PCB tracks 4 are printed, in particular screen-printed, on the printed circuit board 2. The electrical components 3 are arranged on the PCB tracks 4.

The printed circuit board 2 is advantageously opaque and translucent, so that light emitted by the LEDs can shine through in a diffusely scattering manner. The printed circuit board 2 thus also forms a diffuser.

A cover 5 is provided to protect the electrical components 3, in particular the LEDs, and to form the emblem. This cover 5, for example, is formed from polycarbonate (PC) and/or acrylonitrile-butadiene-styrene (ABS) and/or from one or more other materials. For example, this cover 5 is chrome-plated. It is then also referred to as a chrome cover, for example. In a chromium-plated embodiment of the cover 5, the cover 5 is formed, for example, from polycarbonate and acrylonitrile-butadiene-styrene (PC/ABS) or from acrylonitrile-butadiene-styrene (ABS) or from one or more other materials. For example, the cover 5 forms a decorative part of component 1. A reflector foil 6, for example white, is arranged on the inner surface of the cover 5 facing the LEDs. By this formation of component 1, the radiation of light of the LEDs shown by means of beams of light S is achieved.

In order to be able to attach the component 1 designed as an emblem to the vehicle, an adhesive tape 7 is also provided in the example shown, which is arranged on an underside of the printed circuit board 2 facing away from the LEDs.

In particular for the component 1, which is designed as an emblem that can be attached to the vehicle, it is necessary to connect the printed circuit board 2 to the cover 5 in such a way that the electrical components 3 on the printed circuit board 2 are protected from environmental influences, which in particular lead to the ingress of moisture and thus cause corrosion of the PCB tracks 4. This protection must also be ensured at temperatures between −30° C. and 80° C. and also at different operating conditions of the component 1. Furthermore, a homogeneous light effect is to be generated by means of LEDs for illuminating the component 1 that is formed as an emblem.

In order to achieve this, for example, full encapsulation of the electrical components 3, for example by means of an UV-adhesive 8, is conceivable. In the case of such an exclusive full encapsulation, the electrical components 3 would be protected against environmental influences at room temperature, but in the case of large temperature differences, the coefficient of thermal expansion of all components of component 1 differ to such an extent that shear forces transmitted from the UV-adhesive 8 to the electrical components 3 are so great that the electrical components 3 are torn from the PCB tracks 4. Furthermore, a homogeneous light effect cannot be generated in this way.

For this reason, the method described here provides for the electrical components 3 first to be pre-fixed to the printed circuit board 2 made of plastic, in particular by means of a fixing adhesive 9, and only then to be fully encapsulated. In other words, after the electrical components 3 have been pre-fixed to the printed circuit board 2,they are fully encapsulated with the UV-adhesive 8, which advantageously also bonds the cover 5 to the printed circuit board 2.

This pre-fixing of the electrical components 3 on the printed circuit board 2 made of plastic prevents the shear forces between the UV-adhesive 8 and the electrical components 3 from becoming too high, and also protects the PCB tracks 4 formed of silver from a chemical reaction with the UV-adhesive 8.

The fixing adhesive 9 is, for example, an acrylate-based adhesive that cures with UV light. The UV adhesive 8 can be an adhesive with two curing mechanisms, in particular an adhesive that cures with UV light and with moisture. The UV adhesive 8 can also be acrylate-based. Such adhesives with two curing mechanisms are marketed, for example, by Delo (www.delo.de) under the brand name DUALBOND®.

During curing by UV light, moisture can be released. The second curing mechanism reabsorbs the moisture and converts it into the polymer. As a result, no residual moisture remains in the finally cured component. The PCB tracks, especially if they are made of silver, are sensitive to corrosion. PCB tracks made of copper form a patina under the influence of moisture, which can change the electrical resistance. The layer of fixing adhesive 9 covers the PCB tracks during the second adhesive step and protects them from the moisture that is temporarily present. Because the printed circuit board 2 is exposed when the fixing adhesive 9 is applied, the moisture produced during curing of the fixing adhesive 9 can escape quickly and completely without damaging the PCB tracks 4.

For pre-fixing, the fixing adhesive 9 is applied, for example by means of a valve, in particular by means of a jet-valve, in a placement device designed in particular as a SMD-circuit board assembler, by means of which the electrical components 3 are also applied to the printed circuit board 2, in particular in such a way that the fixing adhesive 9 wets the PCB tracks 4 and encloses the electrical components 3 and attaches them to the printed circuit board 2. In the case of the LEDs, the fixing adhesive 9 is advantageously applied in such a way that the LEDs are left free in the main direction of beam in order to avoid undesirable color influences due to media changes. As an alternative to applying the fixing adhesive 9 using the placement device, the fixing adhesive 9 can also be applied at different location, i.e. Not necessarily at the location where the placement of the printed circuit board 2 takes place, and/or with a different device. However, the fixing adhesive 9 is then also applied in particular in such a way that the fixing adhesive 9 wets the PCB tracks 4 and encloses the electrical components 3 and attaches them to the printed circuit board 2. In the case of the LEDs, the fixing adhesive 9 is advantageously also applied in such a way that the LEDs are left free in the main direction of beam in order to avoid undesirable color influences due to media changes.

The printed circuit board 2 with the pre-fixed electrical components 3 is bonded to the cover 5 after the fixing adhesive 9 has cured. In this process, an adhesive channel K between the printed circuit board 2 and the cover 5 is completely filled with UV-adhesive 8 and then cured through the translucent printed circuit board 2 by means of an UV-lamp. This form of adhesion means that the shear forces no longer act directly on the individual electrical components 3, but on the entire pre-fixation of all the components involved. As a result, the electrical components 3 remain bonded to the PCB tracks 4 and the component 1 produced by using this process also passes the required general conditions of environmental influences.

The pre-fixation of the electrical components 3 on the printed circuit board 2 can be carried out selectively, as shown in FIG. 2, or two-dimensional, as shown in FIG. 3.

The selective pre-fixation of the electrical components 3 can be implemented in a very space-saving manner and with little material, in particular fixing adhesive 9, and with little effort. With this selective pre-fixation, the electrical components 3 are only fixed selectively on their sides to the printed circuit board 2. However, this selective pre-fixation is considerably weaker than the two-dimensional pre-fixation.

In the case of two-dimensional pre-fixation, the electrical components 3, advantageously including the PCB tracks 4 formed in particular from silver, are enclosed with the fixing adhesive 9. Depending on the electrical component 3, in particular in the case of LEDs, it may be necessary to leave the respective electrical component 3 free at the top and to attach it to the printed circuit board 2 only on all sides, i.e. circumferentially. This two-dimensional pre-fixation is significantly more stable than the selective pre-fixation.

FIG. 1 shows an embodiment of the component 1 without pre-fixation by means of fixing adhesive 9 and without bonding by means of the UV-adhesive 8, whereby no environmentally stable bonding is achieved. As shown by the further embodiment of component 1 in FIG. 4, in contrast to this first embodiment shown in FIG. 1, in order to achieve an environmentally stable bonding, in the method described here, the electrical components 3 are first prefixed to the printed circuit board 2 in the manner described, either selectively or two-dimensional, in particular by means of the fixing adhesive 9. This pre-fixation, i.e. the fixing adhesive 9, is then cured.

Advantageously, the entire circuit board 2 is then plasma treated, in particular also a surface of the LEDs, in particular shortly before complete bonding by means of UV-adhesive 8. This is done in order to prevent delamination of the UV-adhesive 8 from a silicone encapsulation of the LEDs and the resulting formation of air bubbles above the LEDs, as this would result in a change of medium and thus a color inhomogeneity of the light emitted by the LEDs. Due to the plasma treatment, an improvement of the adhesion, in particular of the silicone encapsulation surface of the LEDS, is achieved for the UV-adhesive 8.

In a possible embodiment the method, the reflector foil 6 is also plasma treated in order to achieve a better adhesion of the UV-adhesive 8.

Subsequently, the printed circuit board 2 with the pre-fixed electrical components 3 is bonded to the cover 5. The cover 5 with the reflector foil 6 already arranged therein is placed on the printed circuit board 2 and, as already described above, the adhesive channel K between the printed circuit board 2 and the cover 5 is completely filled with UV-adhesive 8 and then cured through the translucent printed circuit board 2 by means of a UV-lamp.

The adhesive tape 7 can, for example, be applied to the underside of printed circuit board 2 already at the beginning, i.e. before the described method steps, or, for example, at the end, i.e. after the described method steps, or, for example, during the described method sequence.

For an electrical power supply, in particular of the LEDs 3, it is necessary to make electrical contact with the PCB tracks 4 on the printed circuit board 2 with at least one electrical cable 10. This contacting point must be designed in such a way that it can withstand environmental influences, for example temperatures from −30° C. to 90° C., without this contacting point being damaged and the contact becoming loose.

For example, a holding force of the connection of the cable 10 to the PCB tracks 4 must be able to withstand tensile forces of at least 40 N to 50 N, and advantageously only fail after the printed circuit board 2. The problem here is that there is a risk of the contacting coming loose due to temperature changes and environmental influences. Due to the different coefficients of thermal expansion of the materials used and a low connection force to the PCB tracks 4, for example, a thermally induced movement is already sufficient to separate the connection and lead to errors in the contacting.

In order to avoid this and to create an electrically conductive contacting of the printed circuit board 2 that is stable against environmental influences, it is provided, as shown in FIG. 5, in a method for electrically conductive contacting of the printed circuit board 2 that, even before the printed circuit board 2 is printed with the PCB tracks 4, a contact pin 11, which is advantageously made of brass, also referred to as a brass pin, is pressed into a fit of the printed circuit board 2, in particular with a positive fit, and is countersunk into a groove-like recess 12, in particular a milled recess, made in the printed circuit board 2 until a collar formation 13 at a front end of the contact pin 11 rests against a bottom of the groove-like recess 12. Namely, the contact pin 11 is pressed into the printed circuit board 2 from a flat side, in particular the top side, in the direction of an opposite flat side, in particular the bottom side, penetrating the printed circuit board 3, in particular being pressed in with a positive fit, until the collar formation 13 rests against the bottom of the groove-like recess 12.

The printed circuit board 2 is then printed with the PCB tracks 4 and the groove-like recess 12 is completely filled, in particular with silver PCB paste. The front end of the contact pin 11 with the collar formation 13 is therefore advantageously covered with the PCB track 4, in particular of silver, printed in the groove-like recess 12. The collar formation 13 of the contact pin 11 thus prevents movement from the contact pin 11 out of the printed circuit board 2, because it now rests with one contact side against the bottom of the groove-like recess 12, preventing it from being pushed completely through the printed circuit board 2, and the opposite contact side is covered with PCB track 4, so that the contact pin 11 is also prevented from being pushed back. The contact pin 11 is thus securely anchored in the printed circuit board 2.

Subsequently, the printed circuit board 2 can, for example, be finished, assembled and, in the example described here, bonded to the cover 5 in the manner describe above to form the component 1.

For electrically conductive contacting of this contact pin 11 and thus of the printed circuit board 2, in particular of the PCB tracks 4 and thus in particular of the LEDs 3, a crimp sleeve 14 is crimped to the contact pin 11. Starting from the side facing away from the contact pin 11, the cable 10, advantageously with a cable end sleeve 15, is inserted into this crimp sleeve 14, makes electrically conductive contact with the contact pin 11 and is crimped to the crimp sleeve 14. The electrically conductive contacting of cable 10 with the contact pin 11 can thereby take place by direct electrically conductive contact of cable 10, in particular the cable end sleeve 15, with the contact pin 11 and/or via the crimp sleeve 14.

In order to protect the connection made in this way, in particular the electrically conductive contact, against moisture, a shrunk-on hose 16 is then pulled over and shrunk over the entire connection, i.e. in particular over the contact pin 11, the crimp sleeve 14 and at least in sections over the cable 10, in particular over the cable end sleeve 15.

The crimping of the crimp sleeve 14 with the contact pin 11 is carried out in particular in such a way that the contact pin 11 is locked in its position in the printed circuit board 2 by the crimp sleeve 14, whereby in particular a movement of the contact pin 11 in the longitudinal direction of the contact pin 11 is advantageously excluded by the crimp sleeve 14. For this purpose, the crimp sleeve 14 is advantageously crimped to the contact pin 11, as shown in FIG. 5, in such a way that a front end of the crimp sleeve 14 rests against the underside of the printed circuit board 2.

The crimp sleeve 14 thus fulfills a locking function for the contact pin 11 and thereby in particular prevents the contact pin 11 from being pressed back against the press-in direction, which in particular keeps the contact pin 11 in contact with conductive pastes and/or the PCB track 7 at the frontal end of the contact pin 11 in operation.

This form of connection, in particular of electrically conductive contacting, enables electrically conductive contacting of the PCB tracks 4 of the printed circuit board 2, which are formed in particular of silver, with regular electrical cables 10, which withstands temperature and environmental influences. In addition, this also enables simple and, in particular, initially still wireless handling of the component 1, i.e. in particular wireless production, whereby the electrical cables 10 are then connected, for example, only at the end, for example at the end of the production or during assembly of the component 1, in particular on the vehicle.

FIG. 6 shows a schematic representation of this electrical assembly 17 in a top view, whereby only a section of this electrical assembly 17 is shown here for reasons of simplified and clear representation. The electrical components 3 can be a number of LEDs 18 and a number of electrical series resistors 19.

The LEDs 18 and electrical series resistors 19 are divided into several component groups 20, whereby the LEDs 18 and electrical series resistors 19 of each component group 20 being electrically connected in series and the component groups 20 being electrically connected in parallel to each other. An electrical contacting of LEDs 18 and the electrical series resistors 19 takes place via PCB tracks 4, which are formed as screen-printed silver PCB tracks on the printed circuit board 2.

The assembly 17 is part of a component 1 as shown in FIG. 1 and explained above.

With a conventional design of the electrical assembly 17, for example with an arrangement of the LEDs 18 in groups of two and groups of three, each with an electrical series resistor 19 designed for an effective voltage of 10 V, failures of individual LED groups would occur during prescribed electrical load tests, for example with a transient overvoltage of 17 V for 200 minutes, due to massive heat generation of individual electrical series resistors 19, which melt into the printed circuit board 2 formed of thermoplastic material and cut the printed silver PCB tracks. In addition, heat development of the PCB tracks 4 would take place asymmetrically and especially in the area of an electrical voltage supply.

The overheating of the electrical series resistors 19 results from the fact that in the application of the illuminated emblem described here, in particular the illuminated brand emblem intended for attachment to the vehicle, there is no possibility of cooling the electrical assembly 17, in particular the printed circuit board 2, using conventional cooling concepts. In particular, no cooling is possible by air supply, by means of cooling segments or via heat transport to the outside. In particular, in the event of an electrical overvoltage, the electrical series resistors 19 overheat, because this electrical overvoltage drops across the electrical series resistors 19.

The asymmetrical heat distribution results from a resistance drop that cannot be neglected in the printed silver PCB tracks even at short distances. In this case, the electrical resistance drop at the PCB tracks 4 increases with increasing distance from the electrical voltage supply. This electrical resistance, which drops at the PCB tracks 4, thus does not load the respective electrical series resistor 19, but the PCB tracks 4, even in case of overvoltage. As a side effect, different electrical voltages resulting from this also have a negative effect on a light effect generated by LEDs 18.

In order to solve these problems and to implement a thermally stable electrical circuit on the printed circuit board 2 and thus a thermally stable electrical assembly 17 for the component 1 without using additional cooling concepts, thermal management and thermal optimizations are provided, which are described below, in particular on the basis of this example shown schematically in FIG. 6.

In the solution described here, it is provided that component groups 20, which are electrically connected in parallel to each other, each have the same number of LEDs 18; in the example shown two LEDs 18 each, which are electrically connected in series. In addition, the component groups 20 are designed for larger electrical voltages. For this purpose, oversized electrical series resistors 19 are used in particular. In particular, a resistance value of the electrical protective resistors 19 of the respective component group 20 is higher than required for a permissible current flow through the LEDs 18 of the respective component group 20. As a result, even at a normal electrical voltage, more electrical voltage is dropped across the series resistors 19, but the higher series resistors 19 withstand greater loads without overheating.

Furthermore, the electrical series resistors 19 are divided, i.e. Not a single large electrical series resistor 19 is provided in the respective component group 20, but several small electrical series resistors 19, which are electrically connected in series to each other and to the LEDs 18 of its component group 20. The electrical series resistors 19 are advantageously arranged between the LEDs 18, i.e. An electrical series resistor 19 and an LED 18 are arranged alternately in the respective component group 20, as shown in FIG. 6. Here, as already described, two LEDs 18 and thus also two electrical series resistors 19 are provided per component group 20, which are electrically connected in series. Thus, in the respective component group 20, an electrical series resistor 19, then an LED 18, then again an electrical series resistor 19 and then again an LED 18 are arranged and electrically connected in series.

From an electrical point of view, this distribution of the electrical series resistors 19 does not result in any relevant difference, but it does result in optimized heat distribution by avoiding a few strong local heating points and instead achieving a number of heating points over a larger area on the printed circuit board 2 with less heating. That is, this solution achieves a better distribution of the heating series resistors 19 on the printed circuit board 2, whereby a strong heating of the printed circuit board 2 at a few points by means of a few large electrical series resistors 19 is avoided and instead a smaller heating of the printed circuit boards 2 distributed over a large area is achieved at many points by many smaller electrical series resistors 19, which does not damage the printed circuit board 2 and the PCB tracks 4.

Advantageously, the printed PCB tracks 4 are additionally designed with different thicknesses in order to make the proportion of electrical voltage which drops across the PCB tracks 4 more constant. In particular, the PCB tracks 4 are made thicker, in particular wider, in the area of the introduction of electrical voltage and are made increasingly thinner, in particular narrower, with increasing distance from the introduction of electrical voltage.

In the case of series-connected component groups, it may also be expedient to make the PCB tracks further away from the point of voltage introduction thicker, i.e. wider, in order to supply component groups remote from the voltage introduction point with sufficient current.

With this solution, the electrical circuit is thus optimized with respect to thermal management, in particular due to the variable PCB track thickness and an active heat dissipation by the described design and positioning of the electrical series resistors 19.

Examples of the invention are briefly given below:

1. Example of a method for manufacturing a component (1) comprising a printed circuit board (2) and a number of electrical components (3) arranged thereon,

wherein the electrical components (3) are pre-fixed on the printed circuit board (2) formed of plastic by means of a fixing adhesive (9) and then completely encapsulated with an UV-adhesive (8).

2. Method according to example 1

, wherein an emblem is formed, and the printed circuit board (2) formed of polymethylmethacrylate is connected to a chrome-plated cover (5) of polycarbonate and/or acrylonitrile-butadiene-styrene.

3. Method according to example 2

, wherein the printed circuit board (2) is bonded to the chrome-plated cover (5) by completely filling an adhesive channel (K) between the printed circuit board (2) and the chrome-plated cover (5) with the UV-adhesive (8) and subsequently irradiating the UV-adhesive (8) through the translucent printed circuit board (2) by means of a UV-lamp and thereby curing it.

4. Method according to one of the preceding examples

, wherein the fixing adhesive (9) for pre-fixing the electrical components (3) is applied at least in sections to the printed circuit board (2) and the electrical components (3) by means of a valve on a placement device by which the electrical components (3) are applied to the printed circuit board (2).

5. An example of an electrical assembly (17) comprising a printed circuit board (2) and a number of LEDs (18) arranged thereon, wherein

the printed circuit board (2) is made of plastic,

the LEDs (18) are divided into several component groups (20), the LEDs (18) of each component group (20) being electrically connected in series and the component groups (20) being electrically connected in parallel with each other, each component group (20) comprising a number of electrical series resistors (5) connected electrically in series with the LEDs (18) of the respective component group (20), an electrical series resistor (19) and at least one LED (18) being arranged alternately in succession, characterized in that

a resistance value of the electrical series resistors (19) of the respective component group (20) is higher than required for a permissible current flow through the LEDs (18) of the respective component group (20), and

PCB tracks (4) on the printed circuit board (2) have a different thickness at different positions of the printed circuit board (2).

6. Electrical assembly (17) according to example 5

, wherein the PCB tracks (4) are formed as silver PCB tracks by means of screen printing.

7. Electrical assembly (17) according to example 4 or 5

, wherein the component groups (20) each have two LEDs (18).

8. Electrical assembly (17) according to one of the examples 4 to 6

, wherein the component groups (20) each have two electrical series resistors (19).

9. Example of a method for electrically conductive contacting of a printed circuit board (2), in particular in combination with a method according to examples 1 to 4

, wherein a contact pin (11) of brass is pressed into the printed circuit board (2) in a form-fitting manner penetrating the printed circuit board (2), until a collar formation (13) at a front end of the contact pin (5) rests against a bottom of a groove-like recess (12) in the printed circuit board (2), this front end being covered with a PCB track (4) of silver printed into the groove-like recess (12), wherein the contact pin (11) is crimped with a crimp sleeve (14), wherein an electrical cable (10) is inserted into the crimp sleeve (14), electrically conductively contacted with the contact pin (11) and crimped with the crimp sleeve (14), and wherein a shrunk-on hose (16) is arranged over the contact pin (11), the crimp sleeve (14) and at least in sections over the electrical cable (10).

10. Method according to example 9

, wherein the electrical cable (10) is inserted into the crimp sleeve (14) with a cable end sleeve (15) arranged thereon.

11. Method according to example 9 or 10,

wherein the printed circuit board (2) is assembled before the contact pin (11) is crimped to the crimp sleeve (14).

12. Method according to one of the examples 10 or 11

, wherein

the printed circuit board (2) is bonded to at least one other component before the contact pin (11) is crimped to the crimp sleeve (14).

### REFERENCE LIST

1 Component

2 Printed Circuit Board (PCB)

3 electrical component

4 PCB track

5 Cover

6 Reflector foil

7 Tape

8 UV-adhesive

9 Fixing adhesive

10 Cable

11 Contact pin

12 Recess

13 Collar shaping

14 Crimp barrel

15 cable end sleeve

16 Shrinkable tubing

17 Assembly

18 LEDs

19 Series resistor

20 Component group

K Adhesive channel

S Beam of light

1. A method for manufacturing a component comprising a printed circuit board and a number of electrical components arranged thereon, wherein PCB tracks of the printed circuit board and contacts of the electrical components are electrically connected to each other wherein
the electrical components are pre-fixed on the printed circuit board, which is formed from plastic, by means of a fixing adhesive and the PCB tracks and the contacts are covered with it for corrosion protection and are then completely encapsulated with a UV-adhesive.

2. Method according to claim 1, wherein, an emblem is formed, and the printed circuit board formed of polymethylmethacrylate is connected to a chrome-plated cover of polycarbonate and/or acrylonitrile-butadiene-styrene.

3. Method according to claim 2, wherein, the printed circuit board is bonded to the chrome-plated cover by completely filling an adhesive channel between the printed circuit board and the chrome-plated cover with the UV-adhesive and subsequently irradiating the UV-adhesive through the translucent printed circuit board by means of a UV-lamp and thereby curing it.

4. Method according to claim 1, wherein, the fixing adhesive for pre-fixing the electrical components is applied at least in sections to the printed circuit board and the electrical components by means of a valve on a placement device by which the electrical components are applied to the printed circuit board.

5. A method according to, claim 1, wherein,
a moisture-curing adhesive is used as the UV adhesive.

6. An electrical assembly comprising a printed circuit board and a number of LEDs arranged thereon, wherein, the printed circuit board is formed of plastic, —the LEDs being divided into a number of component groups, the LEDs of each component group being electrically connected in series and the component groups being electrically connected in parallel with each other, each component group comprising a number of electrical protective resistors electrically connected in series with the LEDs of the respective component group, wherein an electrical protective resistor and at least one LED are arranged alternately.

7. An electrical assembly according to claim 6, wherein,
a resistance value of the electrical series resistors of the respective component group is higher than required for a permissible current flow through the LEDs of the respective component group, and/or
PCB tracks on the printed circuit board have a different thickness at different positions of the printed circuit board.

8. Electrical assembly according to claim 6 wherein,
the PCB tracks are formed as silver PCB tracks by means of screen printing.

9. Electrical assembly according to
claim 6 wherein, the component groups each have two LEDs.

10. Electrical assembly according to
claim 6, wherein the component groups each have two electrical series resistors.

11. Method for electrically conductive contacting of the printed circuit board of the component manufactured by the method according to claim 1 wherein a contact pin of brass is pressed into the printed circuit board in a form-fitting manner penetrating the printed circuit board, until a collar formation at a front end of the contact pin rests against a bottom of a groove-like recess in the printed circuit board, this front end being covered with a PCB track of silver printed into the groove-like recess, wherein the contact pin is crimped with a crimp sleeve, wherein an electrical cable is inserted into the crimp sleeve, electrically conductively contacted with the contact pin and crimped with the crimp sleeve, and wherein a shrunk-on hose is arranged over the contact pin, the crimp sleeve and at least in sections over the electrical cable.

12. Method according to claim 11
, wherein the electrical cable is inserted into the crimp sleeve with a cable end sleeve arranged thereon.

13. Method according to claim 11, wherein, the printed circuit board is assembled before the contact pin is crimped to the crimp sleeve.

14. Method according to claim 11
, wherein,
the printed circuit board is bonded to at least one other component before the contact pin is crimped to the crimp sleeve.
